(19) United States
(12) Patent Application Publication
(10) Pub. No.: US 2025/0306168 A1
(43) Pub. Date: Oct. 2, 2025

(54) SIGNAL GROUP DELAY COMPUTATION METHOD AND SIGNAL GROUP DELAY COMPUTATION SYSTEM

(71) Applicant: Realtek Semiconductor Corp., Hsinchu (TW)

(72) Inventors: Chih-Chieh Wang, Hsinchu (TW); Wei-Kai Chen, Hsinchu (TW)

(73) Assignee: Realtek Semiconductor Corp., Hsinchu (TW)

(21) Appl. No.: 19/095,052

(22) Filed: Mar. 31, 2025

(30) Foreign Application Priority Data
Apr. 2, 2024 (TW) 113112449

(51) Int. Cl. G01S 7/40

(52) U.S. Cl. CPC G01S 7/40

(57) ABSTRACT

A signal group delay computation method uses a signal group delay computation system including a signal generation device and a signal analysis device. The signal group delay computation method includes: (a) the signal generation device generates a first input signal to the signal analysis device; (b) the device under test receives the first input signal to generate a first output signal; (c) the signal analysis device performs time-domain alignment on the first output signal and the first input signal to generate a second output signal; (d) the signal analysis device performs frequency alignment on the second output signal and the first input signal to generate a third output signal; and (e) the signal analysis device computes a relative signal group delay based on the first input signal and the third output signal.

### BACKGROUND OF THE INVENTION

### 1. Field of the Invention

The present invention relates to a signal group delay computation method and a signal group delay computation system, and particularly relates to a signal group delay computation method and a signal group delay computation system which allows a device under test may have input signals and output signals with different frequencies while having a lower PAPR (Peak-to-Average Power Ratio).

### 2. Description of the Prior Art

In recent years, various wireless technologies have launched indoor positioning technologies. Compared with outdoor positioning devices, indoor positioning technology has a smaller positioning range but is more accurate. Indoor positioning can use TOF (Time of Flight) to measure distances. TOF can compute the distance between two electronic devices by sending and receiving signals. FIG. 1 is a schematic diagram illustrating a conventional TOF. As shown in FIG. 1, the electronic device D_1 (transmission device) sends a signal to the electronic device D_2 and starts computing time (T0). After the electronic device D_2 (reception device) receives the signal (T1), it records the processing time (T2-T1) of the electronic device D_2 and sends a reply to the electronic device D_1. After the electronic device D_1 receives the reply (T3), it computes the total time (T3-T0) and deducts the processing time of the electronic device D_2 (T2-T1). Thereby the time that the signal propagates in the air can be obtained. Finally, it is multiplied by the speed of light and divided by the round trip times 2, thereby the distance between the two electronic devices can be obtained. The propagation time of signals in electronic devices or lines, the so-called signal group delay, will cause errors in distance measurement. Therefore, it is necessary to measure the signal group delay to correct this error.

The conventional signal group delay measurement method generates an input signal (test signal) to a device under test to generate an output signal to measure the signal group delay. However, conventional signal group delay measurement methods usually require input signals and output signals with the same frequency, or the frequency of the test signal is relatively limited. Some signal group delay measurement methods use multi-tone test signals, but this may result in higher PAPR, thus affecting the accuracy of the signal group delay measurement.

### SUMMARY OF THE INVENTION

One objective of the present invention is to provide a signal group delay computation method which allows the input signal and the output signal of the device under test to have different frequencies while having a lower PAPR.

Another objective of the present invention is to provide a signal group delay computation system which allows the input signal and the output signal of the device under test to have different frequencies while having a lower PAPR.

One embodiment of the present invention discloses a signal group delay computation method, applied to a signal group delay computation system comprising a signal generation device and a signal analysis device, comprising: (a) generating a first input signal to the signal analysis device according to a control signal, by the signal generation device; (b) receiving the first input signal to generate a first output signal to the signal analysis device, by a device under test; (c) aligning the first output signal and the first input signal in a time domain to generate a second output signal, by the signal analysis device; (d) aligning the second output signal and the first input signal in a frequency domain to generate a third output signal, by the signal analysis device; and (e) computing a relative signal group delay according to the first input signal and the third output signal, and computing a signal group delay for that a signal is transmitted from the signal generation device to the device under test and then to the signal analysis device, by the signal analysis device.

Another embodiment of the present invention discloses a signal group delay computation system, comprising: a signal generation device, configured to generate a first input signal to a device under test according to a control signal, wherein the device under test receives the first input signal to generate a first output signal; a signal analysis device, configured to receive the first input signal and to receive the first output signal from the device under test; wherein the signal analysis device performs followings steps: (a) aligning the first output signal and the first input signal in a time domain to generate a second output signal, by the signal analysis device; (b) aligning the second output signal and the first input signal in a frequency domain to generate a third output signal, by the signal analysis device; and (c) computing a relative signal group delay according to the first input signal and the third output signal, and computing a signal group delay for that a signal is transmitted from the signal generation device to the device under test and then to the signal analysis device, by the signal analysis device.

In view of the signal group delay computation method in the aforementioned embodiment, the input signal and the output signal do not need to have the same frequency, thus the frequency of the test signal is less limited. Also, multi-tone test signals are not used, so there will be no high PAPR to affect the accuracy of signal group delay measurement. In addition, the zero-IF transmitter cannot be measured by traditional methods, but the signal group delay computation method provided by the present invention can be used, only needs to be changed from double-ended (I+jQ) to single-ended (I+j0).

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a conventional TOF.

FIG. 2 is a schematic diagram illustrating a signal group delay computation system according to one embodiment of the present invention.

FIG. 3 is a schematic diagram illustrating a trigger signal and a test signal of the signal group delay computation system in FIG. 2.

FIG. 4 is a schematic diagram illustrating a signal group delay computation system according to another embodiment of the present invention.

FIG. 5 is a flow chart illustrating operations of the signal group delay computation system shown in FIG. 2, according to one embodiment of the present invention.

FIG. 6 and FIG. 7 are schematic diagrams illustrating time offset compensation and a frequency offset according to one embodiment of the present invention.

FIG. 8 is a schematic diagram illustrating the operation of smoothing phase differences.

FIG. 9 is a flow chart illustrating a signal group delay computation method according to one embodiment of the present invention.

### DETAILED DESCRIPTION

In the following descriptions, the term “first”, “second”, “third” in following descriptions are only for the purpose of distinguishing different one elements, and do not mean the sequence of the elements. For example, a first device and a second device only mean these devices can have the same structure but are different devices.

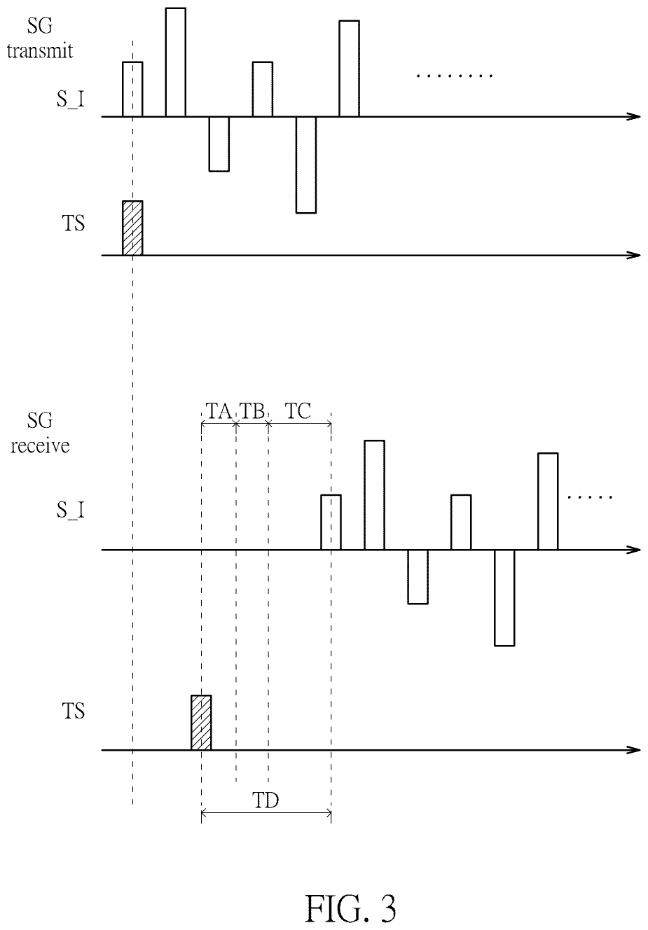

FIG. 2 is a schematic diagram illustrating a signal group delay computation system 200 according to one embodiment of the present invention. The signal group delay computation system 200 may also be named as the signal group delay computation device 200. As shown in FIG. 2, the signal group delay computation system 200 comprises a signal generation device SG and a signal analysis device SA. The signal generation device SG generates a test signal. This test signal is named as an input signal S_I before being input to the device under test DUT, and is named as an output signal S_O after being received and output by the device under test DUT. The signal analysis device SA receives the input signal S_I and the output signal S_O and computes the signal group delay based on the input signal S_I and the output signal S_O. The steps for computing signal group delay will be explained for more detail below. The signal generation device SG may comprise a processing circuit, or a variety of logic units, or a variety of active components/passive components to perform its functions. Similarly, the signal analysis device SA may comprise a processing circuit, or a variety of logic units, or a variety of active components/passive components to perform its functions.

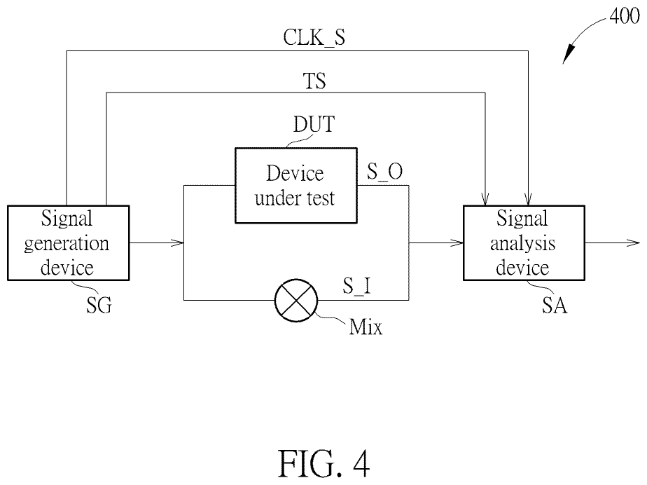

The signal generation device SG and the signal analysis device SA can perform a synchronization mechanism to ensure that their operations are synchronized. In one embodiment, the signal generation device SG and the signal analysis device SA use the same synchronization clock signal CLK_S, and the signal generation device SG generates a trigger signal TS to the signal analysis device SA for synchronization. FIG. 3 is a schematic diagram illustrating a trigger signal and a test signal of the signal group delay computation system in FIG. 2. As shown in FIG. 3, the signal generation device SG generates the input signal S_I (test signal) and the trigger signal TS, and the signal analysis device SA receives the output signal S_O generated by the device under test DUT. and the trigger signal TS. The signal analysis device SA starts or prepares to start computing the signal group delay after receiving the trigger signal TS.

There is usually a delay TD between the output signal S_O received by the signal analysis device SA and the trigger signal TS. In one embodiment, the delay TD comprises three types of delays TA, TB and TC. The delay TA is usually an irregular delay caused by device settings. For example, if the signal generation device SG and the signal analysis device SA operate for a period of time, the delay TA may occur due to changes in device conditions. Also, the mode switching of the signal generation device SG and the signal analysis device SA may also produce the delay TA. Besides, the signal generation device SG may also produce the delay TA when generating a test signal. Delay TB is a fixed delay caused by the environment, such as the delay caused by the signal transmission line. The delay TC is the signal group delay caused by the device under test DUT. The following embodiments can be used to compute this signal group delay.

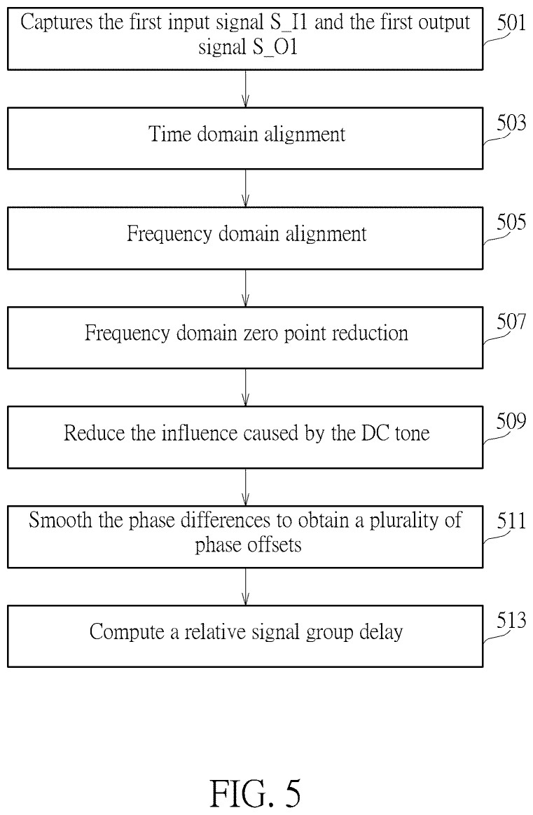

Please return to FIG. 2. In the embodiment of FIG. 2, the input signal S_I and the output signal S_O have the same frequency. However, the device under test DUT may up-convert or down-convert the input signal S_I, so that the input signal S_I and the output signal S_O have different frequencies. In such case, if the signal group delay is computed directly using the input signal S_I and the output signal S_O with different frequencies, incorrect values may be obtained. FIG. 4 is a schematic diagram illustrating a signal group delay computation system 400 according to another embodiment of the present invention. In addition to the components shown in FIG. 2, the signal group delay computation system 400 further comprises a mixer Mix, which can change an input frequency of the input signal S_I so that an output frequency of an output signal S_O received by the signal analysis device SA is identical with the input frequency of the input signal S_I.

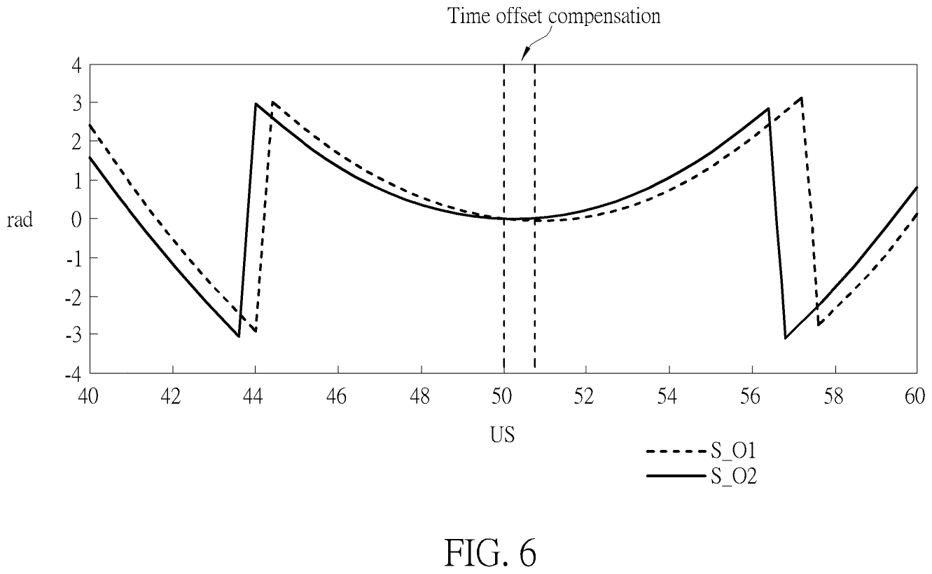

The steps for computing the signal group delay will be explained in detail in FIG. 5 below. In one embodiment, it is first confirmed that the signal generation device SG will not cause a delay or that the delay is negligible before starting the step of computing the signal group delay. Specifically, this determining step generates a reference input signal S_R (i.e., another input signal) within a predetermined time of generating the input signal S_I, and then computes a second time offset between the input signal S_I and the output signal S, to compute a third time offset between the reference input signal S_R and the output signal S_O. When the difference between the second time offset and the third time offset is smaller than a difference threshold (that is, the signal generation device SG will not cause delay or cause a negligible delay), the step of computing the signal group delay is started. Oppositely, if the difference is larger than the difference threshold (that is, the signal generation device SG causes a non-negligible delay), the step of computing the signal group delay is not performed.

FIG. 5 is a flow chart illustrating operations of the signal group delay computation system shown in FIG. 2, according to one embodiment of the present invention. Please also note that for the convenience of explanation, in the flow chart of FIG. 5, the first input signal S_I1 is used to represent the input signal S_I received by the signal analysis device SA, and the first output signal S_O1 is used to represent the output signal S_O received by the signal analysis device SA. Also, other names will be used to represent the signals generated according to the input signal S_I or the output signal S_O. The flowchart in FIG. 5 contains the following steps:

### Step 501

The signal analysis device SA captures the first input signal S_I1 and the first output signal S_O1.

In one embodiment, in order to avoid the influence of signal jitter, signals of the input signal S_I and the output signal S_O for a plurality of signal periods (for example, 100 signal periods) are captured for subsequent computations.

### Step 503

The signal analysis device SA aligns the first output signal S_O1 and the first input signal S_I1 in the time domain to generate a second output signal S_O2.

In one embodiment, a plurality of first time offsets of the first output signal S_O1 and the first input signal S_I1 within a plurality of signal periods are computed, and a maximum time offset among the first time offsets is used to compensate the first output signal S_O1 to generate the second output signal S_O2.

In one embodiment, the first output signal S_O1 is Fourier transformed, time-shifted in the frequency domain, and then returned to the time domain to be performed an inner product with the first input signal S_I1, and such step is repeated to find a maximum time offset within a plurality of signal cycles. One example of its specific equation can be as follows:

$$S\_O2temp ( t\_offset ) = IFFT ( FFT ( S\_O1 ) {e}^{j ω t \_ offset} \\ Corre 2 ( f\_offset ) = S\_I1 \cdot S\_O2temp ( t\_offset ) \\ S\_O2 = S\_O2temp ( t\_offset , max )$$

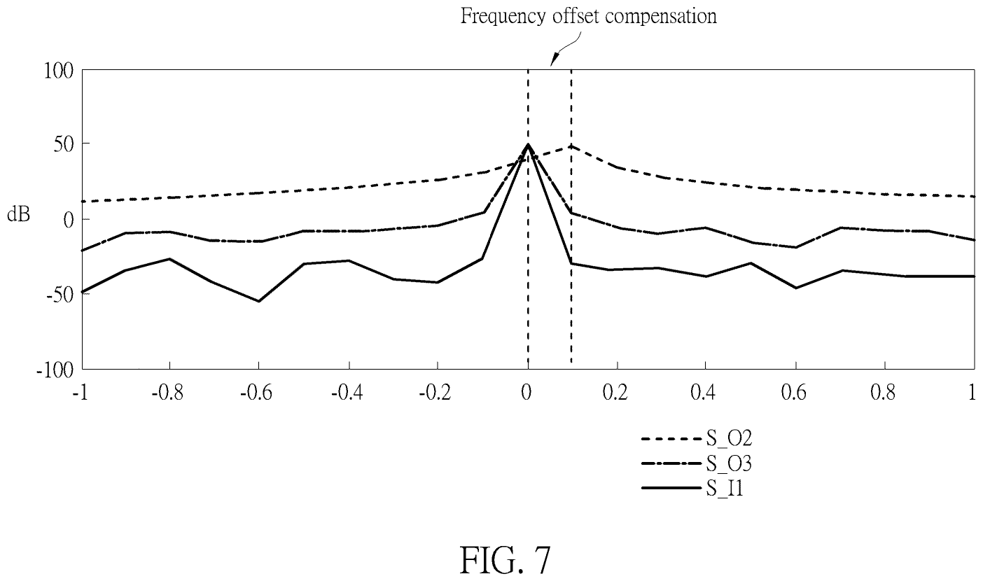

This maximum time offset (t_offset, max) can be regarded as the overall time offset of the signal caused by the device under test DUT (that is, the delay TC in FIG. 3). In one embodiment, the first output signal S_O1 is compensated according to the maximum time offset (t_offset, max) to generate the second output signal S_O2. As shown in FIG. 6, the first output signal S_O1 forms a second output signal S_O2 after compensation. The waveform of the second output signal S_O2 will be the same as or similar with the waveform of the first input signal S_I1. Since the waveform of the second output signal S_O2 highly overlaps with the waveform of the first input signal S_I1, the waveform of the first input signal S_I1 is not shown in FIG. 6.

### Step 505

The signal analysis device SA aligns the second output signal S_O2 and the first input signal S_I1 in the frequency domain to generate a third output signal S_O3.

In one embodiment, a plurality of frequency offsets of the second output signal S_O2 and the first input signal S_I1 within a plurality of signal periods are computed; and a maximum frequency offset among the frequency offsets is used to compensate the second output signal S_O2 to generate the third output signal S_O3.

In one embodiment, the second output signal S_O2 is frequency-shifted in the time domain, and then to be performed an inner product with the first input signal S_I1, and this step is repeated to find the maximum frequency offset. One example of the specific equation can be as follows:

$$S\_O3temp ( f\_offset ) = {S\_O2e}^{j 2 π tf \_ offset} \\ Corre 3 ( f\_offset ) = S\_I1 \cdot S\_O3temp ( f\_offset ) \\ S\_O3 = S\_O3temp ( f\_offset , max )$$

In one embodiment, the second output signal S_O2 is compensated according to the maximum frequency offset (f_offset, max) to generate the third output signal S_O3. As shown in FIG. 7, the second output signal S_O2 generates the third output signal S_O3 after compensation. The peak value of the third output signal S_O3 is the same as the peak value of the first input signal S_I1.

### Step 507

Perform a frequency domain zero point reduction step to the third output signal S_O3 to generate a fourth output signal S_O4, and perform a frequency domain zero point reduction step to the first input signal S_I1 to generate a second input signal S_I2.

Under certain conditions, if the signal intercepted in step 501 is too long, there will be more zero points in the frequency domain. In such case, frequency domain zero point reduction steps such as down-sampling can be used to reduce zero points. One example of the specific equation can be as follows:

$$S\_O4 = down sampling ( FFT ( S\_O3 ) ) \\ S\_I2 = down sampling ( FFT ( S\_I1 ) )$$

### Step 509

Reduce the influence which the DC tone causes to the phase of the fourth output signal S_O4 to generate a fifth output signal S_O5.

If the center of the waveform frequency band of the test signal is DC, its phase will be influenced by the DC audio. In such case, the average value of the two measurement points on the left and right of the DC can be taken to replace its value. One example of the specific equation can be shown as follows:

$$S\_O5 = ignore DC ( S\_O4 )$$

### Step 511

Smooth the phase differences between the second input signal S_I2 and the fifth output signal S_O5 to obtain a plurality of phase offsets.

For more detail, by subtracting the phases of the second input signal S_I2 and the phases of the fifth output signal S_O5, a plurality of phase differences can be obtained. The smoothing means taking the average of the plurality of phase differences as the phase offset, for example, taking the average of 20 phase differences as the phase offset.

### Step 513

Differentiate the phase offsets with respect to at least one angular frequency and add a negative sign to compute a relative signal group delay, and add the maximum time offset computed in step 503 to the relative signal group delay to compute the overall signal group delay.

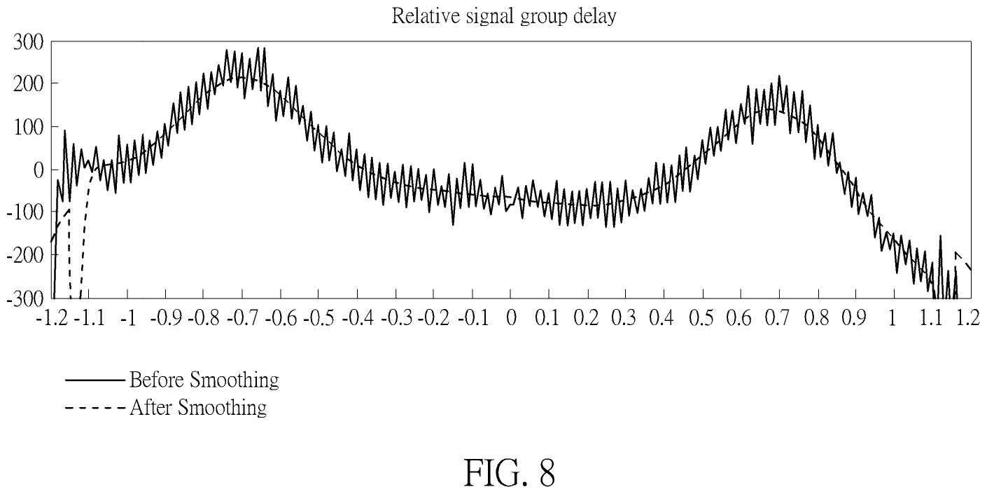

In one embodiment, step 511 can be skipped and the phase difference can be directly differentiated with respect to at least one angular frequency to compute the relative signal group delay. In this case, the signal waveform of the relative signal group delay will have an obvious non-smooth condition. As shown in FIG. 8, the signal waveform of the relative signal group delay will have an obvious saw-tooth waveform without performing the smoothing in step 511, that is, the fluctuation in a short period of time is more obvious. Oppositely, the signal waveform of the relative signal group delay will have a flatter waveform after performing the smoothing in step 511, that is, the fluctuation in a short period of time is low.

In addition, since the relative signal group delay mainly reflects the delay caused by the frequency offset, the maximum time offset computed in step 503 is added to it to compute the signal group delay. In one embodiment, the signal group delay is further computed based on the delay caused by the environment (that is, the delay TB in FIG. 3). For example, if the signal analysis device SA receives the input signal S_I output by the mixer Mix as shown in FIG. 4, then because the input signal S_I has been delayed by the mixer Mix, the delay caused by the mixer Mix must be deducted to acquire the actual signal group delay.

The steps shown in FIG. 5 can be used to measure various devices or components. For example, it can be used to measure the transmission path, the reception path, or the transmission path and the reception path of the signal transceiver device, but it is not limited. In addition, the scope of the present invention is not limited to comprise all the steps shown in FIG. 5. Persons skilled in the art can delete or modify some steps according to actual requirements. For example, the flowchart in FIG. 5 can remove at least one of steps 507, 509, and 511. In such case, the signal processed in step 513 will also change accordingly. For example, if steps 507, 509, and 511 are all removed, then step 513 will compute the relative signal group delay according to the first input signal S_I1 and the third output signal S_O3. In another example, if steps 509 and 511 are both removed, step 513 will compute the relative signal group delay according to the second input signal S_I2 and the fourth output signal S_O4. Such variations should also fall in the scope of the present invention.

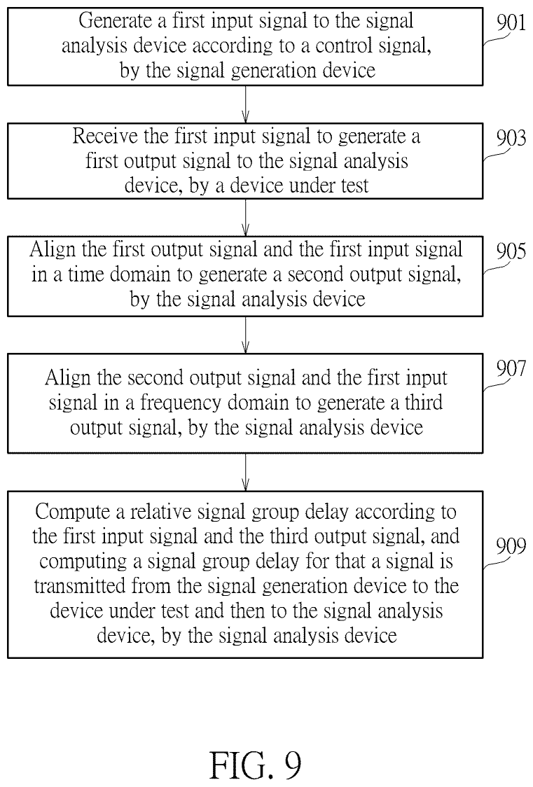

In view of above-mentioned embodiments, a signal group delay computation method can be obtained. FIG. 9 is a flow chart illustrating a signal group delay computation method according to one embodiment of the present invention. This signal group delay computation method is applied a signal group delay computation system. The signal group delay computation system comprises a signal generation device (such as SG in FIG. 2) and a signal analysis device (such as SA in FIG. 2). The signal group delay computation method comprises the following steps:

### Step 901

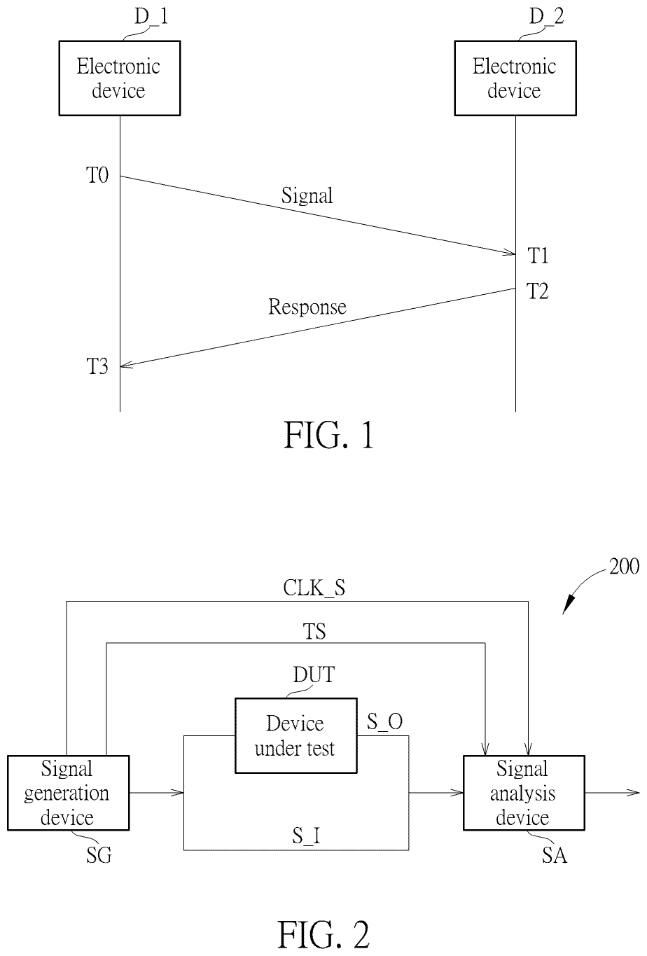

Generate a first input signal (e.g., the input signal S_I in FIG. 1) to the signal analysis device according to a control signal, by the signal generation device.

The control signal can be generated by a control circuit (such as a processing circuit) inside or outside to the signal generation device.

### Step 903

Receive the first input signal to generate a first output signal (e.g., the output signal S_O in FIG. 1) to the signal analysis device, by a device under test (e.g., the device under test DUT in FIG. 2).

### Step 905

Align the first output signal and the first input signal in a time domain to generate a second output signal (e.g., the second output signal S_O2 in FIG. 5), by the signal analysis device

### Step 907

Align the second output signal and the first input signal in a frequency domain to generate a third output signal (e.g., the third output signal S_O3 in FIG. 5), by the signal analysis device.

### Step 909

Compute a relative signal group delay according to the first input signal and the third output signal, and computing a signal group delay for that a signal is transmitted from the signal generation device to the device under test and then to the signal analysis device, by the signal analysis device.

The embodiment in FIG. 9 corresponds to the example in FIG. 5 that does not comprise steps 507-511. As mentioned above, if at least one of steps 507-511 is comprised, the signals used to compute the relative signal group delay will be different. Other detail steps in FIG. 9 can be acquired based on above-mentioned embodiments, thus are omitted for brevity here. After computing the signal group delay, it can be used in various applications according to the signal group delay. If the signal group delay is used in the aforementioned TOF positioning method, the signal propagation time in the air can be compensated based on the signal group delay to compute the precise distance between the transmission device and the reception device.

The waveforms used in the signal group delay computation method provided by the present invention is not limited, but the usage of waveforms with smaller PAPR may have a better accuracy. For example, a two-terminal input (I+jQ) chirp signal can be used.

In view of the signal group delay computation method in the aforementioned embodiment, the input signal and the output signal do not need to have the same frequency, thus the frequency of the test signal is less limited. Also, multi-tone test signals are not used, so there will be no high PAPR to affect the accuracy of signal group delay measurement. In addition, the zero-IF transmitter cannot be measured by traditional methods, but the signal group delay computation method provided by the present invention can be used, only needs to be changed from double-ended (I+jQ) to single-ended (I+j0).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A signal group delay computation method, applied to a signal group delay computation system comprising a signal generation device and a signal analysis device, comprising:
(a) generating a first input signal to the signal analysis device according to a control signal, by the signal generation device;
(b) receiving the first input signal to generate a first output signal to the signal analysis device, by a device under test;
(c) aligning the first output signal and the first input signal in a time domain to generate a second output signal, by the signal analysis device;
(d) aligning the second output signal and the first input signal in a frequency domain to generate a third output signal, by the signal analysis device; and
(e) computing a relative signal group delay according to the first input signal and the third output signal, and computing a signal group delay for that a signal is transmitted from the signal generation device to the device under test and then to the signal analysis device, by the signal analysis device.

2. The signal group delay computation method of claim 1, wherein the step (e) further comprises:
performing a frequency domain zero point reduction step to the third output signal to generate a fourth output signal; and
performing the frequency domain zero point reduction step to the first input signal to generate a second input signal;
computing the relative signal group delay according to the second input signal and the fourth output signal.

3. The signal group delay computation method of claim 2, wherein the step (e) further comprises:
reducing influence which a DC tone causes to the fourth output signal to generate a fifth output signal; and
computing the relative signal group delay according to the second input signal and the fifth output signal.

4. The signal group delay computation method of claim 3, wherein the step (e) further comprises:
smoothing a plurality of phase differences between the second input signal and the fifth output signal to acquire a plurality of phase offsets; and
computing the relative signal group delay according to the phase offsets.

5. The signal group delay computation method of claim 4, wherein the step (e) further comprises:
differentiating the phase offsets with respect to at least one angular frequency and adding a negative sign to compute the relative signal group delay.

6. The signal group delay computation method of claim 1, wherein the step (c) comprises:
computing a plurality of first time offsets of the first output signal and the first input signal in a plurality signal periods; and
using a maximum time offset among the first time offsets to compensate the first output signal to generate the second output signal.

7. The signal group delay computation method of claim 6, further comprising:
adding the relative signal group delay to the maximum time offset to compute the signal group delay.

8. The signal group delay computation method of claim 1, wherein the step (d) comprises:
computing a plurality of frequency offsets of the second output signal and the first input signal in a plurality of signal periods; and
using a maximum frequency offset among the frequency offsets to compensate the second output signal to generate the third output signal.

9. The signal group delay computation method of claim 1, wherein the signal group delay computation system further comprises a mixer for changing an input frequency of the first input signal, thereby an output frequency of the first output signal received by the signal analysis device is identical with the input frequency.

10. The signal group delay computation method of claim 1, further comprising:
generating a reference input signal within a predetermined time of generating the first input signal;
computing a second time offset between the first input signal and the first output signal;
computing a third time offset between the reference input signal and the first output signal;
wherein the step (c), the step (d) and the step (e) are performed if a difference between the second time offset and the third time offset is smaller than a difference threshold;
wherein the step (c), the step (d) and the step (e) are not performed if the difference is larger than the difference threshold.

11. A signal group delay computation system, comprising:
a signal generation device, configured to generate a first input signal to a device under test according to a control signal, wherein the device under test receives the first input signal to generate a first output signal;
a signal analysis device, configured to receive the first input signal and to receive the first output signal from the device under test;
wherein the signal analysis device performs followings steps:
(a) aligning the first output signal and the first input signal in a time domain to generate a second output signal, by the signal analysis device;
(b) aligning the second output signal and the first input signal in a frequency domain to generate a third output signal, by the signal analysis device; and
(c) computing a relative signal group delay according to the first input signal and the third output signal, and computing a signal group delay for that a signal is transmitted from the signal generation device to the device under test and then to the signal analysis device, by the signal analysis device.

12. The signal group delay computation system of claim 11, wherein the step (c) further comprises:
performing a frequency domain zero point reduction step to the third output signal to generate a fourth output signal; and
performing the frequency domain zero point reduction step to the first input signal to generate a second input signal;
computing the relative signal group delay according to the second input signal and the fourth output signal.

13. The signal group delay computation system of claim 12, wherein the step (c) further comprises:
reducing influence which a DC tone causes to the fourth output signal to generate a fifth output signal; and
computing the relative signal group delay according to the second input signal and the fifth output signal.

14. The signal group delay computation system of claim 13, wherein the step (c) further comprises:
smoothing a plurality of phase differences between the second input signal and the fifth output signal to acquire a plurality of phase offsets; and
computing the relative signal group delay according to the phase offsets.

15. The signal group delay computation system of claim 14, wherein the step (c) further comprises:
differentiating the phase offsets with respect to at least one angular frequency and adding a negative sign to compute the relative signal group delay.

16. The signal group delay computation system of claim 11, wherein the step (a) comprises:
computing a plurality of first time offsets of the first output signal and the first input signal in a plurality signal periods; and
using a maximum time offset among the first time offsets to compensate the first output signal to generate the second output signal.

17. The signal group delay computation system of claim 16, further comprising:
adding the relative signal group delay to the maximum time offset to compute the signal group delay.

18. The signal group delay computation system of claim 11, wherein the step (b) comprises:
computing a plurality of frequency offsets of the second output signal and the first input signal in a plurality of signal periods; and
using a maximum frequency offset among the frequency offsets to compensate the second output signal to generate the third output signal.

19. The signal group delay computation system of claim 11, wherein the signal group delay computation system further comprises a mixer for changing an input frequency of the first input signal, thereby an output frequency of the first output signal received by the signal analysis device is identical with the input frequency.

20. The signal group delay computation system of claim 11, wherein the signal analysis device further performs following steps:
generating a reference input signal within a predetermined time of generating the first input signal;
computing a second time offset between the first input signal and the first output signal;
computing a third time offset between the reference input signal and the first output signal;
wherein the step (c), the step (d) and the step (e) are performed if a difference between the second time offset and the third time offset is smaller than a difference threshold;
wherein the step (c), the step (d) and the step (e) are not performed if the difference is larger than the difference threshold.
